(19) United States
(12) Patent Application Publication
(10) Pub. No.: US 2018/0190897 A1
(43) Pub. Date: Jul. 5, 2018

(54) MECHANICALLY STRENGTHENED PIEZOELECTRIC SENSOR FOR STRUCTURAL HEALTH MONITORING

(71) Applicant: Broadsens Corp., Milpitas, CA (US)

(72) Inventors: Chang Zhang, San Jose, CA (US); Shuangwen Liu, Shanghai (CN); Lei Liu, San Ramon, CA (US)

(73) Assignee: Broadsens Corp., Milpitas, CA (US)

(21) Appl. No.: 15/859,666

(22) Filed: Jan. 1, 2018

Related U.S. Application Data
(60) Provisional application No. 62/442,049, filed on Jan. 4, 2017.

(51) Int. Cl. H01L 41/113; H01L 41/047; H01L 41/053; H01L 41/187; H05K 1/03; H05K 1/18; G01H 11/08

(52) U.S. Cl. CPC H01L 41/1132; H01L 41/0475; H01L 41/053; H05K 2201/05; H05K 1/0393; H05K 1/181; G01H 11/08; H01L 41/187

(57) ABSTRACT

The present invention discloses a mechanically strengthened piezoelectric sensor for Structural Health Monitoring applications. The sensor includes a two-sided piezo ceramic component, a sensor encapsulation, and at least two wires. The sensor encapsulation has an indented side that forms a recessed area. The recessed area has a supporting structure. The two-sided piezo ceramic component is mounted into the recessed area of the encapsulation and is supported by the supporting structure with the side facing outwards slightly lower than the upper edge of the recessed area. The supporting structure of the encapsulation provides mechanical strength to the piezo ceramic component. The wires are attached to the electrodes of the piezo ceramic component and extend out of the encapsulation. Alternatively, the mechanically strengthened piezoelectric sensor may further include a Printed Circuit Board (PCB). The piezo ceramic component is mounted on the PCB. Then, the PCB is mounted into the recessed area of the encapsulation and is supported by the supporting structure with the side facing outwards slightly lower than the upper edge of the encapsulation.

### CROSS-REFERENCE TO RELATED APPLICATION

This application claims priority to U.S. provisional patent application Ser. No. 62/442,049, filed Jan. 4, 2017, the entire content of which is incorporated herein by reference.

### FIELD OF INVENTION

This invention generally relates to the field of sensor technology.

### BACKGROUND OF THE INVENTION

A piezoelectric sensor can be used to measure pressure, force, acceleration, or strain by converting mechanical stress to electrical charge. It can also be used to generate sound by converting electrical charge to mechanical waves. In Structural Health Monitoring (SHM) applications, the piezoelectric sensors can be used to generate and receive ultrasonic waveforms to detect structural damages. The main component of a piezoelectric sensor is a two-sided piezo ceramic component. One side of the piezo ceramic component is bonded to the target structure permanently to send and receive ultrasonic signals. A typical piezoelectric sensor for SHM is thin, rigid, and very fragile. The sensor electrodes are can easily get electrically shorted when the sensor is mounted to the target structure if the surface of the target structure is electrically conductive. This can negatively affect the performance of the sensor. Similarly, when multiple sensors are mounted to the target structure, these sensors could be electrically shorted together. Therefore, it requires great care to bond the piezoelectric sensor to the target structure. One approach is to mount the piezoelectric sensor to a flexible circuit and glue the flexible circuit to the structure with epoxy. This approach provides better protection than bare piezoelectric sensors, but the piezoelectric sensors can still be damaged during the installation process if the flexible circuit is bent on the piezo disc area, and it is still very easy to short the sensor electrodes with the target structure. Installation of such flexible circuit piezoelectric sensors also requires extensive labor and special tools, such as vacuum bags and air pumps. After installation, the piezoelectric sensors, even protected by the flexible circuits, are still vulnerable to external impacts and strains. Therefore, it is desirable to have a mechanically strengthened piezoelectric sensor for SHM that is easy to install, resistant to external impacts, and more robust in operation.

### SUMMARY OF THE INVENTION

The present invention discloses a mechanically strengthened piezoelectric sensor for SHM applications. In one embodiment, the sensor includes a two-sided piezo ceramic component, a sensor encapsulation, and at least two wires. The sensor encapsulation has an indented side that forms a recessed area. There is a supporting structure inside the recessed area. The supporting structure may be manufactured as an integral part of the encapsulation (e.g., through injection molding). Alternatively, the supporting structure may be manufactured separately and assembled inside the recessed area of the encapsulation. The two-sided piezo ceramic component has at least two electrodes. It is mounted into the recessed area of the encapsulation and is supported by the supporting structure inside the encapsulation with the side facing outwards slightly lower than the upper edge of the recessed area. The supporting structure of the encapsulation provides mechanical strength to the piezo ceramic component. The wires are attached to the electrodes of the piezo ceramic component and extend outside the encapsulation.

In another embodiment, the mechanically strengthened piezoelectric sensor further includes a Printed Circuit Board (PCB). The piezo ceramic component is soldered on the PCB. Then, the PCB is mounted into the recessed area of the encapsulation and is supported by the supporting structure. The supporting structure inside the encapsulation provides mechanical strength to the PCB. The wires are attached to the PCB and electrically connected to the electrodes of the piezo ceramic component. The wires also extend outside the encapsulation.

### BRIEF DESCRIPTION OF THE DRAWINGS

The subject matter, which is regarded as the invention, is particularly pointed out and distinctly claimed in the claims at the conclusion of the specification. The foregoing and other features and also the advantages of the invention will be apparent from the following detailed description taken in conjunction with the accompanying drawings. Additionally, the leftmost digit of a reference number identifies the drawing in which the reference number first appears.

FIG. 1A is an exploded view of a mechanically strengthened piezoelectric sensor, according to one embodiment of the invention.

FIG. 1B is a cross-sectional view of the mechanically strengthened piezoelectric sensor shown in FIG. 1A.

FIG. 2A is an exploded view of a mechanically strengthened piezoelectric sensor, according to one embodiment of the invention.

FIG. 2B is a cross-sectional view of the mechanically strengthened piezoelectric sensor shown in FIG. 2A.

### DETAILED DESCRIPTION

This invention discloses a mechanically strengthened piezoelectric sensor for SHM applications. In one embodiment, the sensor includes a two-sided piezo ceramic component, a sensor encapsulation, and at least two wires. The two-sided piezo ceramic component is mounted into the encapsulation directly. There is a supporting structure inside the encapsulation to provide mechanical strength to the piezo ceramic component. The wires are attached to the electrodes of the piezo ceramic component and extend outside the encapsulation.

In another embodiment, the mechanically strengthened piezoelectric sensor further includes a PCB. The piezo ceramic component is soldered on the PCB. Then, the PCB is mounted into the encapsulation. There is a supporting structure inside the encapsulation to provide mechanical strength to the PCB. The wires are attached to the PCB and electrically connected to the electrodes of the piezo ceramic component. The wires also extend outside the encapsulation. The wires can be but are not limited to coaxial cable or twisted wire.

The encapsulation can be made of different materials to meet mechanical and environmental requirements. Typical materials include but are not limited to metal, plastic, ceramic, composite, rubber or a combination of the above. The shape of the encapsulation can be round, triangle, square, rectangular or others. The encapsulation is designed to improve strength, resist impacts, and simplify the installation process.

In one embodiment of the invention, the encapsulation has an indented side that forms a recessed area. The piezo ceramic component or the PCB is installed inside the recessed area with the side of the piezo ceramic component facing outwards slightly lower than the upper edge of the recessed area. This design allows maximal contact area between the piezo ceramic component and the target structure, while preventing short circuit between the piezoelectric sensor and the structure. Most environmental impacts, tensile forces, and vibrations are absorbed by the encapsulation, shielding the piezo ceramic component. To install the sensor to the target structure, one can apply pressure to the encapsulation, without touching the piezo ceramic component. Since the piezo ceramic component is slightly lower than the upper edge of the encapsulation, the encapsulation takes the pressing force and protects piezo ceramic component. Moreover, the small gap between the piezoelectric sensor and the target structure prevents potential electrical short circuit. The gap should be filled with epoxy or glue to allow the ultrasound wave transfer between the piezoelectric sensor and the structure. No special tools, such as vacuum bags and air pumps, are required during installations and this design significantly simplifies the installation.

In another embodiment of the invention, the encapsulation has an opening to allow the wires to extend outside the encapsulation. The opening can be on the sidewall of the encapsulation or on the bottom side of the encapsulation. When the opening is on the sidewall of the encapsulation, the opening can be large enough to be on the same level as the upper edge and the bottom edge of the encapsulation, or just a hole through the sidewall of the encapsulation. The encapsulation may have extensions around the opening to hold the wires in place to further protect the wire and the piezo ceramic component from external pushing or pulling forces. The wires can be further protected and/or held by adding an optional protection layer, such as a plastic tube or a heat shrinkable tube.

In one embodiment, glue, epoxy or other non-conductive material is used to fill the gap between the piezo ceramic component and the encapsulation as well as the gap between the wires coming out of the encapsulation and the encapsulation and/or the extension to add additional strength. Waterproof materials and wires may be used to make the piezoelectric sensor waterproof.

In another embodiment of the invention, multiple piezo ceramic components and/or PCBs are protected by a single encapsulation. The encapsulation is designed to support multiple piezo ceramic components and/or PCBs. In another embodiment of the invention, multiple piezo ceramic components are mounted to a single PCB. The PCB is designed to support multiple piezo ceramic components. When multiple piezo ceramic components and/or PCBs are protected by a single encapsulation, each piezo ceramic component and/or PCBs has its attached wires coming out of the encapsulation separately. Alternatively, the piezo ceramic component and/or PCBs can be connected in serial and the wires of the serial connection come out of the encapsulation.

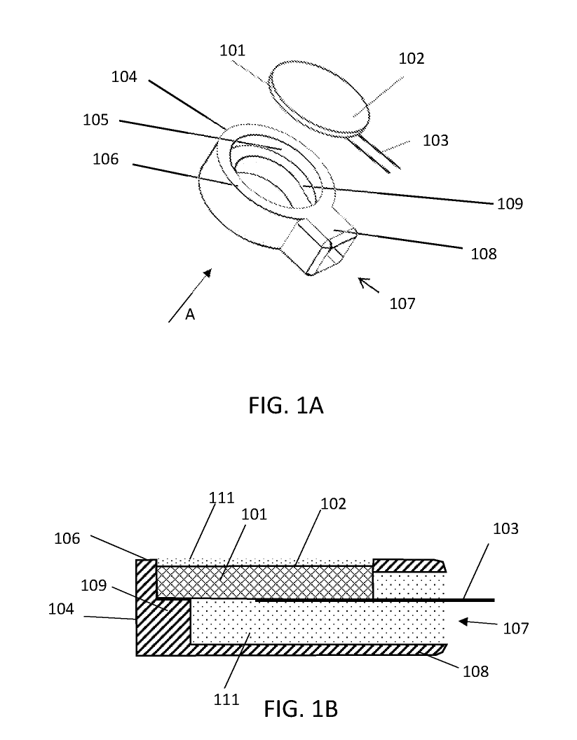

FIG. 1A is an exploded view of a mechanically strengthened piezoelectric sensor, according to one embodiment of the invention. FIG. 1B is a cross-sectional view of the mechanically strengthened piezoelectric sensor shown in FIG. 1A along direction A after being assembled. The piezo ceramic component 101 has wires 103 attached to its electrodes. The piezo ceramic component 101 is mounted to the encapsulation 104 with the side 102 facing outwards. The encapsulation 104 has an indented side 105 that forms a recessed area. The piezo ceramic component 101 is mounted on the supporting structure 109 inside the recessed area formed by the indented side 105 with the side 102 slightly lower than the upper edge 106 of the encapsulation 104. Although the supporting structure 109 is shown as an integral part of the encapsulation 104, it may be a separate component assembled with the encapsulation after manufacturing. Epoxy or glue 111 is filled between the side 102 and the upper edge 106. The encapsulation 104 has an opening 107 on its sidewall to allow the wires 103 to extend out of the encapsulation 104. The encapsulation 104 has optional extension 108 for protecting the wires 103. The extension can be the same height as the encapsulation or shorter than the encapsulation. Any gap inside the mechanically strengthened piezoelectric sensor may be filled with epoxy, glue, or other non-conductive material to further strengthen the whole sensor structure.

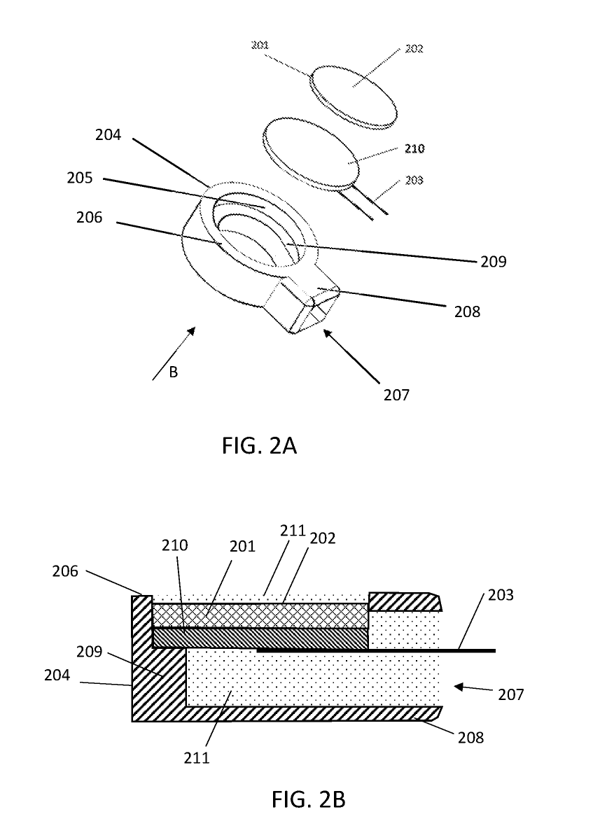

FIG. 2A is an exploded view of a mechanically strengthened piezoelectric sensor, according to one embodiment of the invention. FIG. 2B is a cross-sectional view of the mechanically strengthened piezoelectric sensor shown in FIG. 2A along direction B after being assembled. The piezo ceramic component 201 is soldered to a PCB 210. The wires 203 are attached to the PCB 210 and electrically connected to the electrodes of the piezo ceramic component 201. The PCB 210 is then mounted into a recessed area formed by an indented side 205 of an encapsulation 204. Specifically, the PCB 210 is mounted on a supporting structure 209 inside the encapsulation 204 and the side 202 is slightly lower than the upper edge 206 of the encapsulation 204. Epoxy or glue 211 is filled between the side 202 and the upper edge 206. The encapsulation 204 has an opening 207 to allow the wires 203 to extend out of the encapsulation 204. The encapsulation 204 has optional extension 208 for protecting the wires 203. The extension 208 can be the same height as the encapsulation or shorter than the encapsulation. Any gap inside the mechanically strengthened piezoelectric sensor may be filled with epoxy, glue, or other non-conductive material to further strengthen the whole sensor structure.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

We claim:

1. A mechanically strengthened piezoelectric sensor for Structural Health Monitoring (SHM), comprising:
a sensor encapsulation having an indented side that forms a recessed area with an upper edge, a supporting structure in the recessed area, a sidewall, a bottom side, and an opening through the sidewall or the bottom side;
a two-sided piezo ceramic component connected to a plurality of electrical wires, wherein the two-sided piezo ceramic component is mounted into the recessed area and supported by the supporting structure with a side facing outwards and slightly lower than the upper edge and the plurality of electrical wires extending outside the sensor encapsulation through the opening.

2. The mechanically strengthened piezoelectric sensor of claim 1 further comprises a Printed Circuit Board (“PCB”), wherein the two-sided piezo ceramic component is mounted to the PCB, the PCB and the two-sided piezo ceramic component are mounted into the recessed area and supported by the supporting structure, and the two-sided piezo ceramic component is connected to the plurality of electrical wires via the PCB.

3. The mechanically strengthened piezoelectric sensor of claim 2, wherein each of said plurality of electrical wires has a protection layer.

4. The mechanically strengthened piezoelectric sensor of claim 1, wherein any gap between the two-sided piezo ceramic component and the encapsulation is sealed with glue, epoxy, or waterproof material.

5. The mechanically strengthened piezoelectric sensor of claim 1, wherein any gap between the plurality of electrical wires and the encapsulation is sealed with glue, epoxy, or waterproof material.

6. The mechanically strengthened piezoelectric sensor of claim 1, wherein said piezo ceramic component has a shape of a circle, a ring, a triangle, a square, a rectangle, or a polygon.

7. The mechanically strengthened piezoelectric sensor of claim 1, wherein the encapsulation has a shape of a circle, a ring, a triangle, a square, a rectangle, or a polygon.

8. The mechanically strengthened piezoelectric sensor of claim 1, wherein said encapsulation has an extension around the opening for protecting the plurality of electrical wires.

9. The mechanically strengthened piezoelectric sensor of claim 1, wherein the supporting structure is manufactured as an integral part of the sensor encapsulation through a molding process.

10. The mechanically strengthened piezoelectric sensor of claim 1, wherein the supporting structure is manufactured as a separate component and is assembled with the sensor encapsulation.
